(19) United States
(12) Patent Application Publication
(10) Pub. No.: US 2024/0383432 A1
(43) Pub. Date: Nov. 21, 2024

(54) INDUCTIVE SENSING FOR VEHICLE INTERFACES

(71) Applicant: Tesla, Inc., Austin, TX (US)

(72) Inventors: Pak Heng Lau, Sunnyvale, CA (US); Joris Aerts, San Francisco, CA (US)

(21) Appl. No.: 18/722,351

(22) PCT Filed: Dec. 2, 2022
(86) PCT No.: PCT/US2022/051652

§ 371 Date: Jun. 20, 2024

Related U.S. Application Data
(60) Provisional application No. 63/265,805, filed on Dec. 21, 2021.

(51) Int. Cl. B60R 21/203; B60Q 5/00; B60R 21/015; G01L 1/14; G01L 5/22

(52) U.S. Cl. CPC B60R 21/2035; B60Q 5/003; B60R 21/015; G01L 1/14; G01L 5/221

(57) ABSTRACT

A system for triggering a functionality of a vehicle. The system includes an inductive sensor, a vehicle interface, and a conductive target. The conductive target can be coupled to the vehicle interface and configured to move with the vehicle interface between a first position and a second position relative to the inductive sensor. The first position has a first inductance and the second position has a second inductance different than the first inductance. The system can further include a controller.

### CROSS-REFERENCE TO RELATED APPLICATIONS

This application claims the benefit of U.S. Provisional Application No. 63/265,805, filed Dec. 21, 2021, the entire disclosure of which is hereby incorporated by reference in its entirety.

### TECHNICAL FIELD

The present disclosure relates to systems and methods that employ inductive sensing. More particularly, the present disclosure relates to employing inductive sensing to trigger functionalities of a vehicle (e.g., horn, glove box, lighting, door, screen, etc.).

### BACKGROUND

Generally described, a variety of vehicles, such as electric vehicles, combustion engine vehicles, hybrid vehicles, etc., can be configured with one or more functionalities triggered by mechanical movement (e.g., dynamic springs and mechanical contacts). These functionalities can include, for example, accessing a glove box, controlling lighting, operating a door, controlling a screen, activating turn signals, activating a horn, controlling the climate (for example increasing or decreasing the cabin temperature or increasing or decreasing the fan speed), making a telephone call, or another function or action.

Steering wheel assemblies are associated with a number of automotive applications to allow a user to maneuver a vehicle. Some steering wheel assemblies require the user to activate switches that employ mechanical movements to control certain vehicle functionalities. For example, to activate the horn, the user presses a spring loaded airbag module inwards to close contacts of a switch. The ability to reduce the travel distance of the mechanical switch is limited by the need to avoid mis-triggers from vibration caused by vehicle dynamics, thermal expansion/contraction, and part tolerance and variation. The need to maintain a significant travel distance and gap degrades the appearance of the steering assembly. The mechanical travel also produces undesirable squeaks and noises from springs and contacts. Thus, there is a need to improve on existing mechanical switches to ensure a superior user experience for the life of the vehicle.

### SUMMARY

The present disclosure relates to a steering wheel assembly that employs inductive sensing. The steering wheel assembly includes a steering rim. The steering wheel assembly also includes an airbag module. The steering wheel assembly further includes at least one inductive sensor system (e.g., inductive sensor and target surface) disposed within the steering wheel assembly.

In certain embodiments, when a force is applied, the target surface moves closer to the inductive sensor reducing a distance between the inductive sensor and the target surface. In certain embodiments, material deflects slightly (e.g., micrometer resolution), reducing the distance between the inductive sensor and the target surface. In certain embodiments, this change in distance changes the inductance of the sensor. For example, in certain embodiments, if the target surface is non-ferromagnetic (e.g., aluminum), the inductance decreases with decreasing distance to the target surface. In certain embodiments, if the target surface is ferromagnetic (e.g., iron), inductance increases with decreasing distance to the target surface. In certain embodiments, this change in inductance is measured by an inductance-to-digital converter. When the force is removed, the target surface moves away from the inductive sensor. In certain embodiments, the material returns to its original unstressed shape.

In certain embodiments, a controller is electrically connected to the inductive sensor (e.g., via the inductance-to-digital converter). The controller determines a user input or a gesture made by a user based on the change measured by the inductance-to-digital converter.

An aspect is directed to a system for triggering a functionality of a vehicle that includes an inductive sensor, a vehicle interface, and a conductive target coupled to the vehicle interface and configured to move with the vehicle interface between a first position and a second position relative to the inductive sensor. The first position has a first inductance and the second position has a second inductance different than the first inductance. The system further includes a controller configured to receive a signal from the inductive sensor indicative of a change between the first inductance and the second inductance and trigger the functionality of the vehicle.

A variation of the aspect above is wherein the functionality is activating a horn.

A variation of the aspect above is wherein the vehicle interface is an airbag module.

A variation of the aspect above is wherein the conductive target is disposed on a lower surface of the airbag module.

A variation of the aspect above further comprises a printed circuit board, wherein the inductive sensor is disposed on the PCB.

A variation of the aspect above is wherein the conductive target is metallic.

A variation of the aspect above is wherein the conductive target is Cu tape.

A variation of the aspect above is wherein triggering the functionality comprises emitting a loud or a soft sound.

A variation of the aspect above is wherein the functionality comprises emitting or not emitting a sound.

A variation of the aspect above is wherein the signal is indicative of at least a measure of force applied to the vehicle interface, wherein triggering the functionality comprises emitting a sound, and wherein a volume level of the emitted sound is based at least in part on the measure of the force.

A variation of the aspect above further comprises at least a second inductive sensor, and wherein the measure of force applied to the vehicle interface is based at least on weighing relative input from the inductive sensor and the second inductive sensor.

A variation of the aspect above is wherein the signal is indicative of at least a location of force applied to the vehicle interface, wherein triggering the functionality comprises emitting a sound, and wherein a direction of the emitted sound is based at least in part on the location of the force.

A variation of the aspect above further comprises at least a second inductive sensor, and wherein the location of force applied to the vehicle interface is based at least on weighing relative input from the inductive sensor and the second inductive sensor.

A variation of the aspect above further comprises a memory configured to store values or settings related to the functionality.

A variation of the aspect above further comprises an inductance to digital converter configured to convert the signal to a digital signal.

A variation of the aspect above further comprises a buffer disposed between the inductive sensor and the conductive target.

A variation of the aspect above is wherein the first position differs from the second position by a micrometer.

A variation of the aspect above further comprises an airgap disposed between the inductive sensor and the conductive target.

A variation of the aspect above is wherein the vehicle interface comprises a locking pin configured to secure the vehicle interface to the vehicle.

A variation of the aspect above further comprises a steering wheel assembly having a center portion, and wherein the vehicle interface is sized and shaped so that at least a portion of the vehicle interface fits within the center portion.

A variation of the aspect above is wherein the conductive target is a surface of the vehicle interface.

An aspect is directed to a steering wheel assembly for a vehicle that includes at least one target surface disposed on an airbag module and at least one inductive sensor adapted to generate a signal in response to changes in a measured inductance caused by a change in distance between the at least one inductive sensor and the at least one target surface.

A variation of the aspect above further comprises an inductance to digital converter configured to convert the signal to a digital signal.

A variation of the aspect above further comprises a buffer disposed between the at least one inductive sensor and the at least one target surface.

A variation of the aspect above further comprises a printed circuit board, wherein the at least one inductive sensor is embedded in the printed circuit board.

An aspect is directed to a method for triggering a functionality of a vehicle. The vehicle comprises at least one target surface and at least one inductive sensor disposed relative to the at least one target surface to sense movement of the target surface. The method includes moving the at least one target surface to change a distance between the at least one target surface and the at least one inductive sensor, generating a signal in response to a change in a measured inductance caused by the change in the distance, and triggering the functionality of the vehicle based on the signal.

A variation of the aspect above is wherein the functionality is activating a horn.

A variation of the aspect above is wherein the at least one target surface is disposed on an airbag module.

A variation of the aspect above is wherein the at least one target surface is disposed on a lower surface of the airbag module.

A variation of the aspect above is wherein the at least one target surface is metallic.

A variation of the aspect above is wherein the at least one inductive sensor is disposed on a printed circuit board.

A variation of the aspect above is wherein the printed circuit board comprises a buffer, and wherein the buffer is in contact with the at least one target surface before and after the at least one target surface is moved.

A variation of the aspect above is wherein moving the at least one target surface slightly compresses the buffer.

A variation of the aspect above further comprises converting the signal to a digital signal.

### BRIEF DESCRIPTION OF THE DRAWINGS

The present inventions are described with reference to the accompanying drawings, in which like reference characters reference like elements, and wherein:

FIG. 1 is a block diagram of a system including a steering wheel assembly that has an inductive sensor system for triggering a functionality of a vehicle (e.g., horn, glove box, lighting, door, screen, etc.) according to one embodiment of the present disclosure.

FIG. 2 is a block diagram of a controller and the inductive sensor system from FIG. 1.

FIG. 3 is an exemplary illustration of a vehicle that includes the system of FIG. 1.

FIG. 4 is a view inside the vehicle of FIG. 3 showing the steering wheel assembly in the form of a yoke according to one embodiment of the present disclosure.

FIG. 5 is a plan view of the steering wheel assembly from FIG. 4 with an airbag module removed to reveal the inductive sensor system from FIG. 2 according to an embodiment of the present disclosure.

FIG. 6 is a plan view of an embodiment of the steering wheel assembly from FIG. 5 showing a printed circuit board (PCB) carrying one or more inductive sensors of the inductive sensor system according to an embodiment of the present disclosure.

FIG. 7 is a perspective view of the airbag module showing one or more target surfaces covered by Cu tape positioned to be in register with the one or more inductive sensors when installed into the steering wheel assembly of FIG. 6 according to an embodiment of the present disclosure.

FIG. 8 is a back side perspective view of a right switchpack in an open position showing an inductance to digital converter from FIG. 2 disposed in a receptacle and connected to a printed circuit board (PCB) of the right switchpack by a ribbon cable according to an embodiment of the present disclosure.

FIG. 9 shows top and bottom views of two PCBs similar to the PCB from FIG. 6.

FIG. 10 illustrates another embodiment of the inductive sensor system where the inductance to digital converter is incorporated into the PCB of the right switchpack.

FIG. 11 is a cross-section view through the steering wheel assembly of FIG. 4 showing the inductive sensors in proximity to the target surfaces. FIG. 11 further shows a small gap around an outer perimeter of the airbag module.

FIG. 12 are exemplary charts of sensor data measured by an embodiment of the inductive sensor system of FIG. 2 in response to the user pushing or pulling near the top and bottom of the airbag module.

FIG. 13 is a plan view of an embodiment of the steering wheel assembly from FIG. 5 with the airbag module removed showing the controller integrated into the printer circuit board (PCB) according to an embodiment of the present disclosure.

FIG. 14 is a perspective view of an embodiment of the airbag module showing one or more target surfaces covered by Cu tape positioned to be in register with the one or more inductive sensors when installed into the steering wheel assembly of FIG. 13 according to an embodiment of the present disclosure.

FIG. 15 shows a perspective view of a PCB that integrates the inductance to digital converter and/or the controller from FIG. 2.

FIG. 16 is a partial cross section view taken along lines 16-16 of FIG. 15 showing the one or more inductive sensors integrated into the PCB and positioned underneath and around the one or more buffers. The illustrated PCB comprises four buffers and four inductive sensors positioned underneath and around the four buffers.

FIG. 17 is an exemplary chart of sensor data measured by an embodiment of the inductive sensor system that includes the PCB of FIG. 15 in response to the user pushing or pulling on the airbag module.

### DETAILED DESCRIPTION

Generally described, one or more aspects of the present disclosure relate to buttonless vehicle interfaces which can include, for example, interfaces for activating a horn, accessing a glove box, controlling lighting, operating a door, controlling a screen, activating turn signals, controlling the climate (for example increasing or decreasing the cabin temperature or increasing or decreasing the fan speed), making a telephone call, or another function or action. For ease of explanation, an inductive sensor system includes an inductive sensor and a target surface are described in the context of activating a horn. Of course, the disclosure is not so limited and can be incorporated into other parts of a vehicle for other functionalities.

In certain embodiments, the inductive sensor system is almost static and involves almost no moving parts (e.g., micrometer movements). For example, in certain embodiments, the inductive sensor is placed on a static part or panel. A target surface is disposed in proximity to the inductive sensor so that small movements of the target surface are sensed by the inductive sensor.

In certain embodiments, sensing is achieved by reducing a distance between the inductive sensor and the target surface. In certain embodiments, this change in distance changes the inductance of the sensor. For example, in certain embodiments, if the target surface is non-ferromagnetic (e.g., aluminum), the inductance decreases with decreasing distance to the target surface. In certain embodiments, if the target surface is ferromagnetic (e.g., iron), inductance increases with decreasing distance to the target surface. In certain embodiments, this change in inductance is measured by an inductance-to-digital converter. When the force is removed from the target surface, the target surface moves away from the inductive sensor.

Certain embodiments may also have lower overall mass, smaller packaging volume, simpler control strategy, lower component count, and fewer NVH/BSR risks, which can all contribute to a more positive user experience as compared to known mechanical switches.

Known mechanical switches require a user to close mechanical contacts. For example, to activate the horn, the user presses a spring-loaded airbag module inwards to close contacts of a switch. The ability to reduce the travel distance of the mechanical switch is limited by the need to avoid mis-triggers from vibration caused by vehicle dynamics, thermal expansion/contraction, and part tolerance and variation. The need to maintain a significant travel distance and gap degrades the appearance of the steering assembly. The mechanical travel also produces undesirable squeaks and noises from springs and contacts.

In contrast, the inductive sensor system disclosed herein utilizes inductive sensing coils or sensors to detect an airgap distance between the airbag module and a target surface on the steering wheel rear frame, and outputs a signal when the airgap closes below a certain threshold. In certain embodiments, the sensor is sensitive to micrometer movements. In this way, the inductive sensor system essentially removes the traditional mechanical movement and the associated unsightly gap, greatly improving cosmetics and design.

In certain embodiments, the gain and sensitivity of the inductive sensor system is adjustable by software. For example, in certain embodiments, the force required to activate or trigger the horn can be updatable post-delivery of the vehicle. For example, in certain embodiments, the force required to activate or trigger the horn can be adjusted to allow for dynamic sensitivity based on driving conditions/harshness, or even user preference. In this way, dynamic springs and mechanical contacts of existing horn actuation mechanisms are replaced with static coils and target surfaces, potentially reducing cost and environmental mitigations.

In certain embodiments, the inductive sensor system senses different applied forces (e.g., pressure and/or location on the airbag module) and in response triggers a specific horn sound and/or broadcast direction associated with the applied force. For example, in certain embodiments, the horn sound volume can be proportional to applied forces and/or emitted in a specific direction away from the vehicle. In certain embodiments, the user can reduce the volume of the horn by applying less force to the airbag module.

In certain embodiments, the system rotates the derived direction to take into account any rotation (e.g., steering wheel angle) of the steering wheel. In this way, the broadcast direction of the horn can be true from the driver's perspective regardless of whether the steering wheel is turned. For example, if the steering wheel was turned to a 3 o'clock position for a right turn and the driver presses the horn in the true “up” area of the airbag module, the system would sense that the left portion of the airbag module was pressed. The system can determine the steering wheel angle (e.g., 3 o'clock) and adjust the broadcast direction by rotating the broadcast direction by +90 degrees so that the revised broadcast direction is true forwards as indicted by the driver pressing the horn in the true “up” area.

In certain embodiments, the inductive sensor system functions with an airgap between the inductive sensor and the target surface. In this way, the inductive sensor system functions with an intentional airgap. By having an intentional airgap, the inductive sensor system is robust against part variations (e.g., tolerance stack-up) as well as thermal expansions and contractions which might change a size of the airgap.

The inductive sensor system can be calibrated at any point during the manufacturing process, and can be re-commanded at any point during the life of the steering wheel assembly without employing external measurement equipment. For example, the calibration process can be applied during the manufacturing process automatically, so there is no need for manual calibration. The calibration process can also be applied remotely or in service if a user experiences a degradation in quality (e.g., sensitivity) of horn activation. This degradation can occur if, for example, any of the mechanical contributions in the force/displacement stack of components change over time (e.g., one or more buffers 72 degrade over time and become stiffer or softer). In certain embodiments, this degradation can result in the amount of displacement by the airbag module 18 caused by the same input force to vary over time.

The calibration process can reduce the burden on the vehicle service organization. For example, if a user complains about the high force required to activate the horn, the service team can remotely trigger a re-calibration to address the problem. Thus, this disclosure can not only solve a manufacturing challenge but can also reduce the burden on the vehicle service organization.

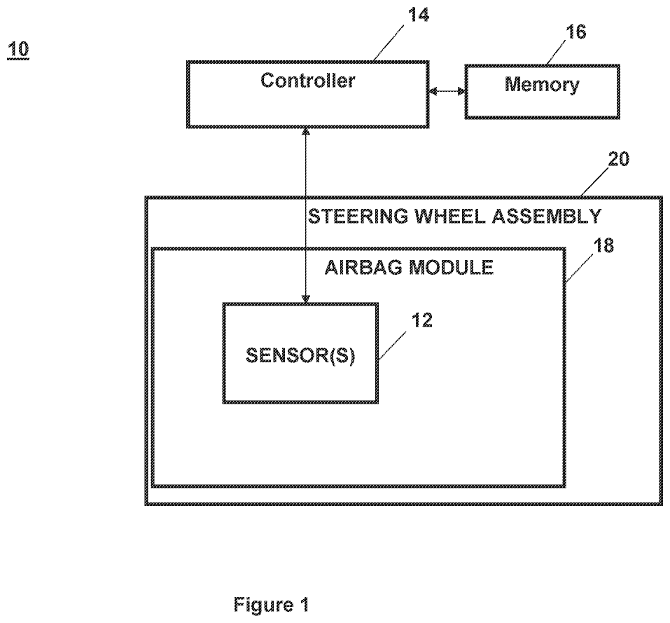

FIG. 1 is a block diagram of a system 10 including a steering wheel assembly 20 that has an inductive sensor system 12 for activating a functionality (e.g., a horn) of a vehicle 40. A user can apply a force to a vehicle interface (e.g., an airbag module 18) which is sensed by the inductive sensor system 12. In certain embodiments, the system 10 can include a controller 14 for controlling the inductive sensor system 12. In certain embodiments, the system 10 can include a memory 16. In certain embodiments, the memory 16 can store values or settings (e.g., calibration values) for the inductive sensor system 12.

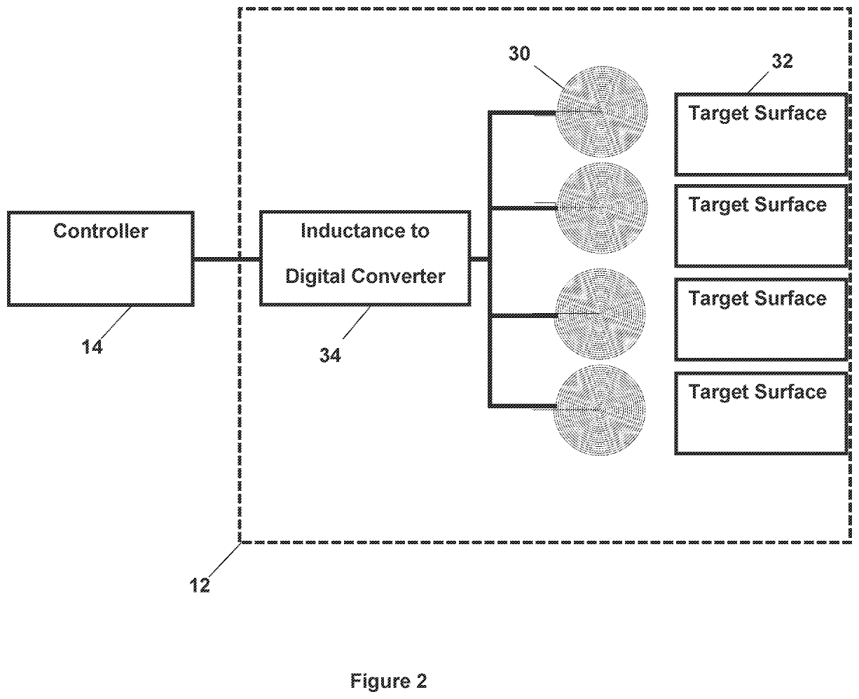

FIG. 2 is a block diagram of the controller 14 and the inductive sensor system 12 from FIG. 1. In certain embodiments, the inductive sensor system 12 comprises one or more inductive sensors 30 and one or more target surfaces 32. In certain embodiments, the one or more target surfaces 32 are disposed on the airbag module 18 within the steering wheel assembly 20. In certain embodiments, the inductive sensor system 12 relies on the interaction of electromagnetic (EM) fields generated by the inductive sensor 30 and the eddy currents being induced on the target surface 32. In certain embodiments, the amount of eddy currents induced on the target surface 32 decreases with an increase in airgap as the target surface 32 now captures a smaller portion of the electromagnetic field generated by the inductive sensor 30. In turn, in certain embodiments, a physical size of the electromagnetic field lines generated by the inductive sensor 30 can be directly proportional to a diameter of the inductive sensor 30.

In certain embodiments, the one or more target surfaces 32 are metallic objects. In certain embodiments, the metallic object interacts with a magnetic field generated by the one or more inductive sensors 30. A metallic object that comprises a material with higher electrical conductivity (a) can be advantageous for inductive sensing. For example, the amount of eddy currents generated on the target surface 32 can be directly related to a of the target material making higher conductivity materials (e.g., copper, aluminum etc.) advantageous targets for use in the inductive sensor system 12 as compared to lower conductivity materials (e.g., bronze, nickel, stainless steel, etc.). For example, in certain embodiments, material such as Cu and Al exhibit larger shifts in inductance with target surface movement resulting in a higher measurement resolution.

In certain embodiments, when a force is applied to the vehicle interface, the target surface 32 moves closer to the inductive sensor 30 reducing a distance between the inductive sensor 30 and the target surface 32. In certain embodiments, material deflects slightly (e.g., micrometer resolution) reducing a distance between the inductive sensor 30 and the target surface 32. In certain embodiments, this change in distance changes the inductance of the sensor 30. For example, in certain embodiments, if the target surface is non-ferromagnetic (e.g., aluminum), the inductance decreases with decreasing distance to the target surface. In certain embodiments, if the target surface is ferromagnetic (e.g., iron), inductance increases with decreasing distance to the target surface. In certain embodiments, this change in inductance is measured by an inductance to digital converter 34. When the force is removed from the target surface 32, the target surface 32 moves away from the inductive sensor 30. In certain embodiments, the material returns to its original unstressed shape.

In certain embodiments, the controller 14 is electrically connected to the at least one inductive sensor 30 (e.g., via the inductance to digital converter 34). The controller 14 can determine a user input or a gesture made by a user on the target surface 32 based on the change measured by the inductance to digital converter 34.

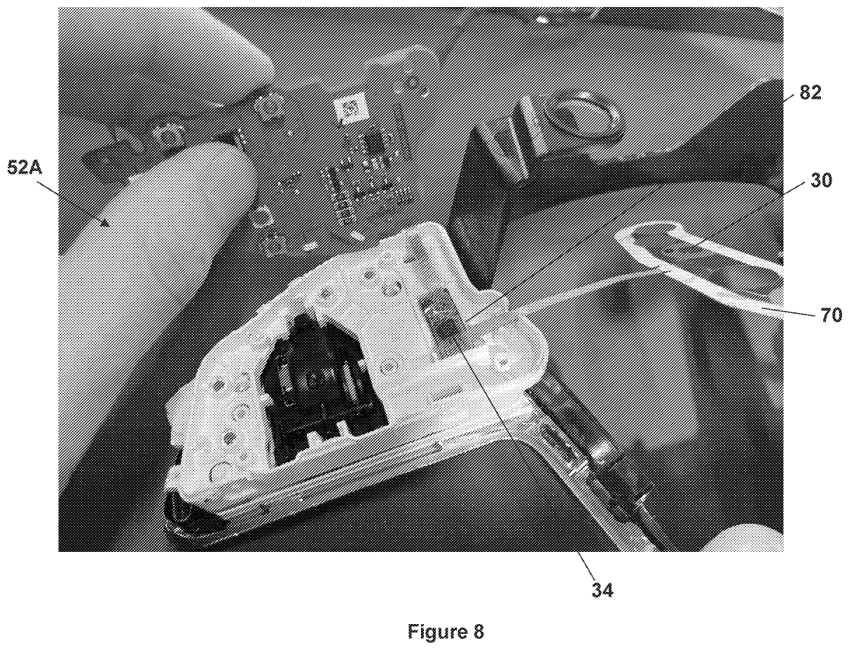

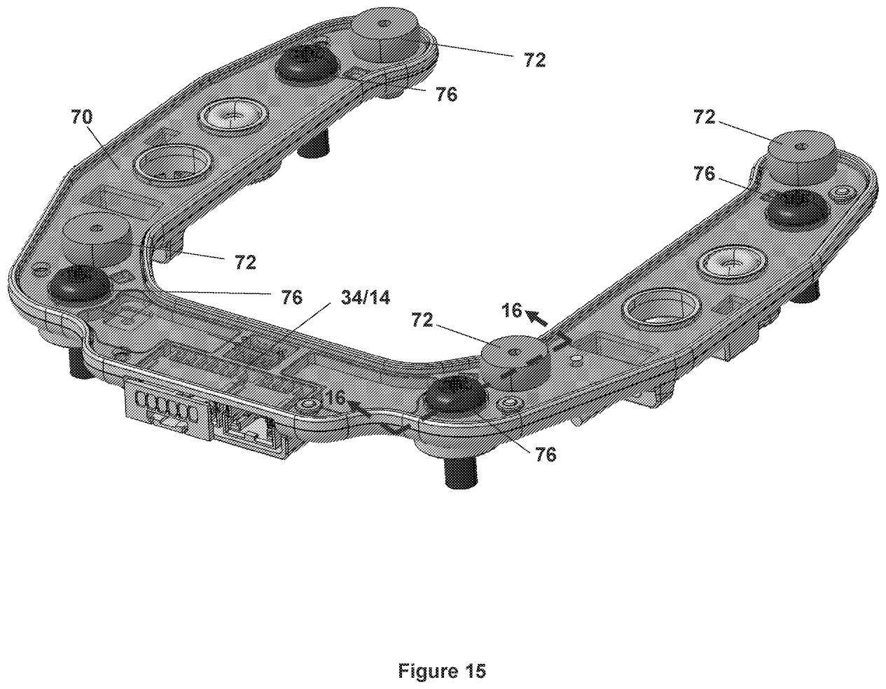

In certain embodiments, the controller 14 is located in the PCB 70. In certain embodiments, the controller 14 is located in the inductive sensor system 12. In certain embodiments, the controller 14 is located in the steering wheel assembly 20. In certain embodiments, the controller 14 is located in the vehicle 40. In certain embodiments that include multiple controllers 14, each controller 14 can be associated with one or more inductive sensors 30. In certain embodiments, the controller 14 is configured as a switchpack 52, 52A (FIG. 8). In certain embodiments, the controller 14 is configured as a PCB 70 (FIG. 15).

In certain embodiments, the controller 14 is configured to control the inductive sensor system 12 during a calibration process. In certain embodiments, the controller 14 is configured to control the inductive sensor system 12, e.g., command operational parameters, during not only the calibration process but also during operation of the vehicle 40 by the user. In certain embodiments, the calibration process is performed in preparation for delivery of the vehicle 40 to the user. In certain embodiments, the calibration process for the inductive sensor system 12 is repeated one or more times after delivery of the vehicle 40 to the user.

In certain embodiments during operation of the vehicle 40, the controller 14 receives electric signals from the inductance to digital converter 34. In certain embodiments, the controller 14 determines user inputs based on the received electric signals from the inductance to digital converter 34. In certain embodiments during operation of the vehicle 40, the controller 14 receives a signal from the one or more inductive sensors 30 (e.g., via the inductance to digital converter 34) when the airbag module 18 is pressed or contacted by the user. In certain embodiments, the inductance to digital converter 34 applies a gain to the sensed signal. In certain embodiments, the signal is in response to the user placing, for example, a finger, in contact with a buttonless vehicle interface.

In certain embodiments during operation of the vehicle 40, the controller 14 generates output signals based on electric signals received from the inductance to digital converter 34. Output signals are embodied as control signals for changing settings of one or more system or functionalities of the vehicle 40. For example, output signal may result in activation of a horn, changing a setting for a left or right turn signal of the vehicle 40, high or low beam headlights of the vehicle 40, windshield wipers of the vehicle 40, voice recognition, an air conditioning unit of the vehicle 40, a lighting system of the vehicle 40, a music system of vehicle 40, and/or changing a setting of a driver-assist mode or an autonomous-driving mode.

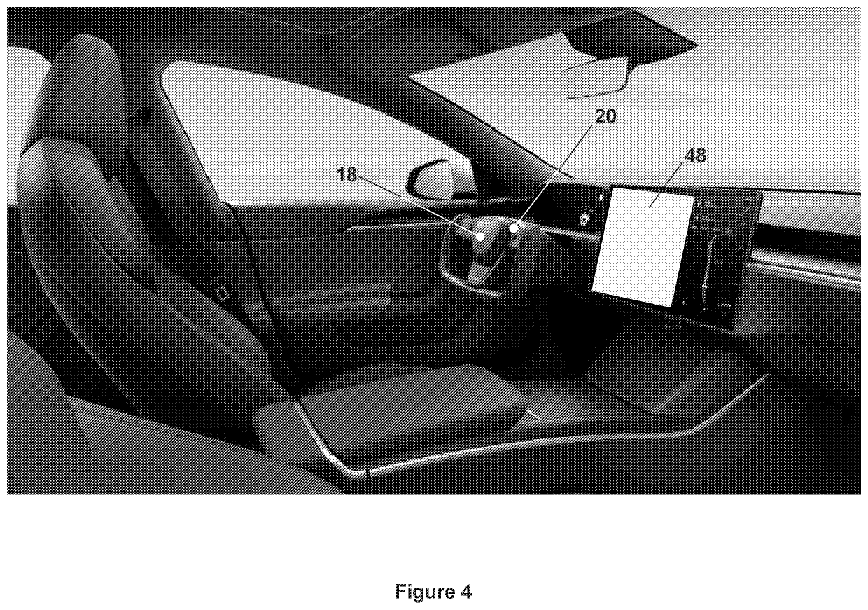

Output signals may be directly sent to a control unit of the vehicle 40 or to individual systems of the vehicle 40. Further, output signals may also be sent to a display unit 48 (FIG. 4). Display unit 48 may be present on the steering wheel assembly 20 or it may be present anywhere in a cab of the vehicle 40 where the user is seated. In certain embodiments, the display unit 48 may include a tablet or smartphone. The display unit 48 may provide notifications to the user regarding change in vehicle system settings or selections made by the user. Output signals may also be transmitted to other remote devices that are connected to the vehicle 40. For example, a tablet or smartphone may be connected to vehicle 40 through short distance communication techniques, for example Bluetooth technology.

In certain embodiments, the controller 14 can be trained such that the controller 14 employs a profile or preferences. The profile or preferences can be stored in the memory 16 as a user profile. The memory 16 can also store mapping of inputs to functionality.

In certain embodiments, the gain of the one or more sensors 30 can be adjusted to control the sensitivity of triggering the horn. In this way, button sensitivity can be precisely tuned by adjusting the gain. For example, the controller 14 can, in certain embodiments, adjusts one or more operational parameters (e.g., gain) of the one or more inductive sensors 30.

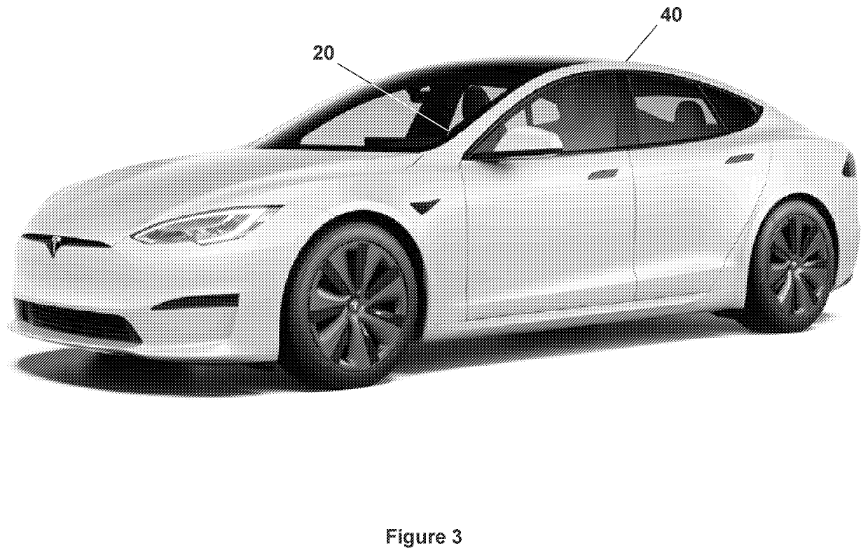

The system 10 can be incorporated into a variety of vehicles 40, for example, a passenger car, a truck, a sport utility vehicle, or a van. In various embodiments, the vehicle 40 is an electric vehicle, a hybrid vehicle, or a vehicle driven by an internal combustion engine. For example, FIG. 3 is an exemplary illustration of a passenger car that includes the system 10 of FIG. 1. FIG. 4 is a view inside the vehicle 40 of FIG. 3 showing the steering wheel assembly 20 in the form of a yoke.

In certain embodiments, each of the one or more target surfaces 32 is physically closest to one of the inductive sensors 30. In certain embodiments that include multiple inductive sensors 30, each target surface 32 can be physically closest to its associated inductive sensor 30. In this way, the target surface 32 is more likely to be sensed by the associated inductive sensor 30 as compared to inductive sensors 30 that are farther away from the target surface 32.

In certain embodiments, the controller 14 utilizes the sensed signal to improve the sensitivity of the inductive sensor system 12. In certain embodiments, the controller 14 calibrates the inductive sensor system 12. For example, in certain embodiments, the controller 14 determines a gain which is then utilized by the inductive sensor system 12.

In certain embodiments, the controller 14 compares the electric signal to data in one or more look-up tables and/or one or more predetermined parameters to at least in part to calibrate the inductive sensor system 12. For example, in certain embodiments, the controller 14 can utilize logic control in the form of a look-up table to map information from the inductive sensor system 12 to operational parameters (e.g., gain) of the inductive sensors 30. In some embodiments, the look-up table can map individual inductive sensors 30 values to determine operational parameters for the inductive sensor system 12. The inductive sensor 30 values can be specified as absolute values that are mapped in the look-up table, ranges of values, binary indications (e.g., on or off), or non-numeric categories (e.g., high, medium, or low). Still further, the look-up table can incorporate weighting values such that the inductive sensor 30 values can have greater impact or are otherwise ordered in a manner that causes the impact of specific input information to influence the determined operational parameters of the inductive sensor system 12.

In certain embodiments, the look-up tables utilized by the controller 14 can be specifically configured to individual vehicles 40. Alternatively, the look-up tables can be common to a set of vehicles 40, such as by vehicle type, geographic location, user type, and the like. The look-up tables may be statically configured with the controller 14, which can be periodically updated. In other embodiments, the look-up tables can be more dynamic in which the frequency of update can be facilitated via communication functionality associated with the vehicle 40.

In certain embodiments, the look-up table can be configured in a programmatic implementation. Such programmatic implementations can be in the form of mapping logic, a sequence of decision trees, or similar logic. In other embodiments, the controller 14 may incorporate machine learning implementations that may require more refined operation of the inductive sensor system 12.

In certain embodiments, the controller 14 provides signals corresponding to the determined operational parameters of the inductive sensor system 12 in the form of an operational profile. In certain embodiments, the operational profile is customized for the specific inductive sensor system 12 and steering wheel assembly 20.

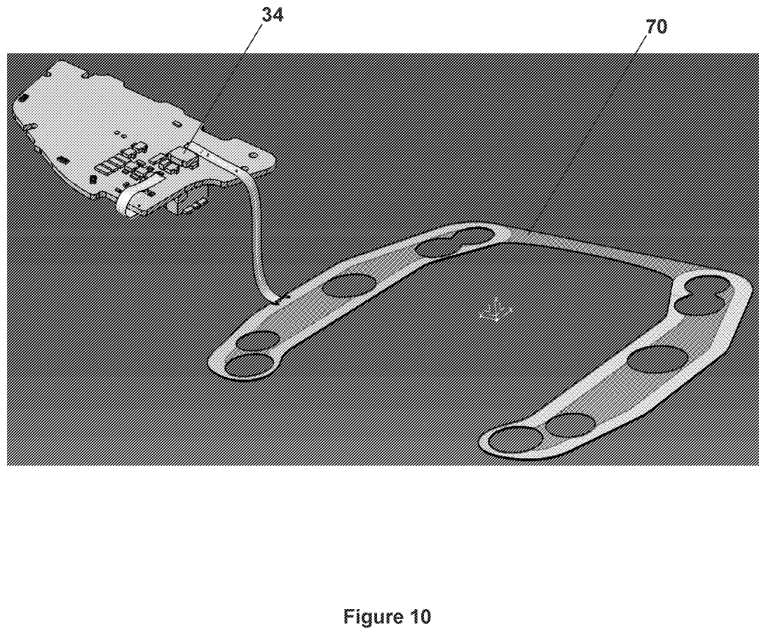

While the inductance to digital converter 34 and the controller 14 are illustrated as separate components within the system 10, in certain embodiments, the inductance to digital converter 34/controller 14 are incorporated into another component or each other. For example, as is illustrated in FIG. 10, the inductance to digital converter 34 is incorporated into the PCB of the right switchpack 52A.

The inductance to digital converter 34/controller 14 may embody a single microprocessor or multiple microprocessors. Numerous commercially available microprocessors can be configured to perform the functions of the inductance to digital converter 34/controller 14. The inductance to digital converter 34/controller 14 may include all the components required to run an application such as, for example, the memory 16, a secondary storage device, and a processor, such as a central processing unit. Various other known circuits may be associated with the controller 14, including power supply circuitry, signal-conditioning circuitry, communication circuitry, and other appropriate circuitry.

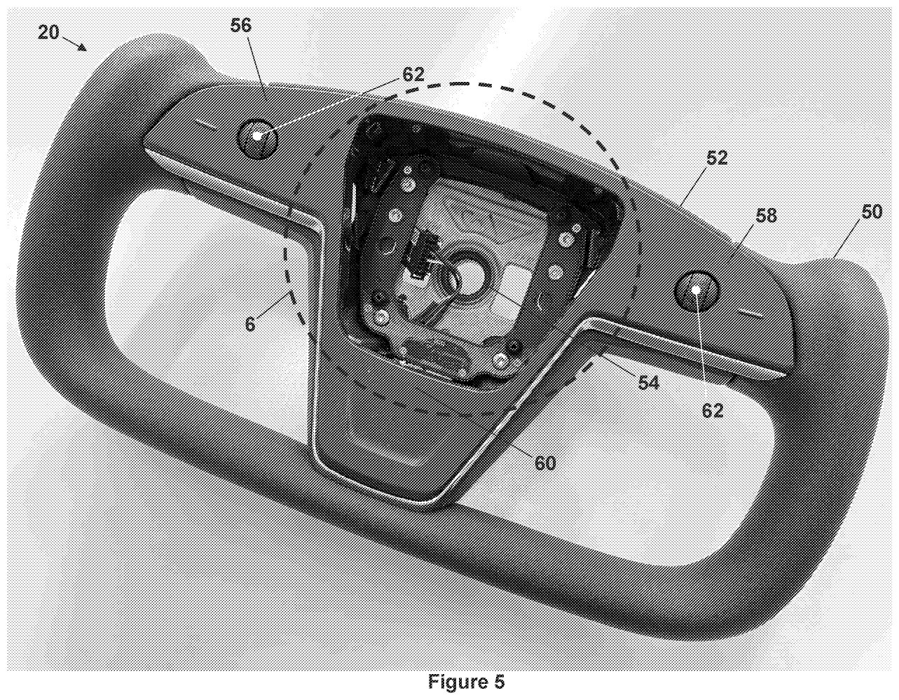

FIG. 5 is a plan view of the steering wheel assembly 20 from FIG. 4 with both an airbag module 18 and the inductive sensor system 12 removed. The steering wheel assembly 20 allows a user to maneuver the vehicle 40. The steering wheel assembly 20 includes a steering rim 50. In the illustrated embodiment, the steering rim 50 is generally rectangular in shape. Of course the steering rim 50 can have any other shape including a circular shape.

One or more switchpacks 52 are connected to the steering rim 50. For example, in certain embodiments, the steering wheel assembly 20 includes a right switchpack and a left switchpack. In the illustrated embodiment, the steering wheel assembly 20 includes a central portion 54. In the illustrated embodiment, the steering wheel assembly 20 includes a first portion 56 extending horizontally from a left side of the central portion 54 and a second portion 58 extending horizontally from a right side of the central portion 54. Additionally, a third portion 60 extends vertically from a lower side of the central portion 54.

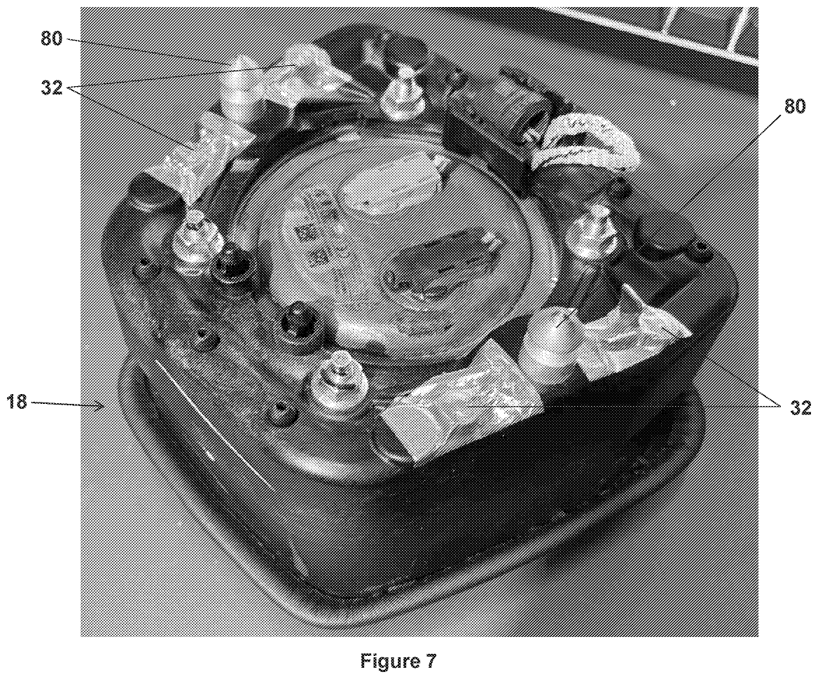

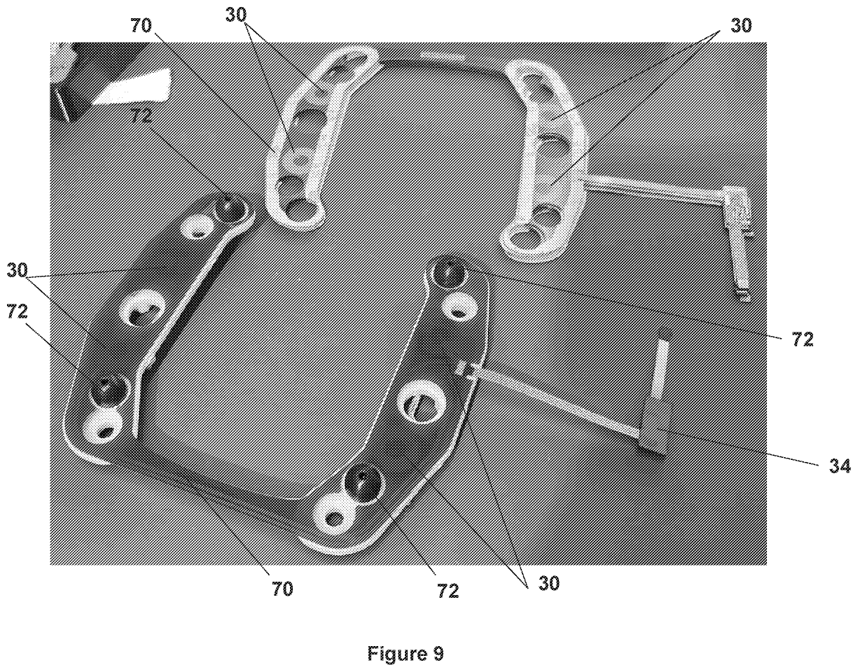

In certain embodiments, the central portion 54 is used to house the inductive sensor system 12 and the airbag module 18 (FIGS. 7 and 9). In certain embodiments, the inductive sensor system 12 is disposed below the airbag module 18 in the central portion 54. The airbag module 18 and the inductive sensor system 12 are removed from the central portion 54 in FIG. 5 for clarity. In certain embodiments, the steering wheel assembly 20 comprises one or more scroll wheels 62 or other mechanical switches for changing or updating vehicle functionalities.

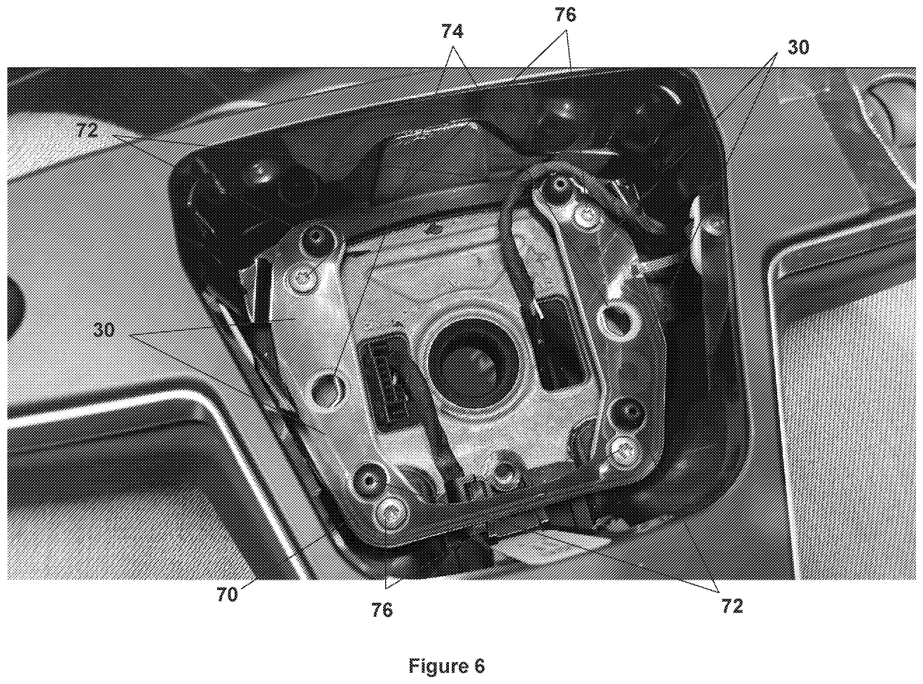

FIG. 6 is a plan view of the steering wheel assembly 20 from FIG. 5 with a printed circuit board (PCB) 70 carrying the one or more inductive sensors 30 from FIG. 2 installed in the steering wheel assembly 20. In the illustrated embodiment, there are four inductive sensors 30. Of course the disclosure is not limited to the illustrated number of inductive sensors 30 and can include more or fewer inductive sensors 30 (e.g., one sensor 30, two sensors 30, three sensors 30, five sensors 30, six sensors 30, etc.). The locations of the one or more inductive sensors 30 in FIG. 6 are only exemplary and can instead be in any other position within the central portion 54 that is in proximity to the airbag module 18 so as to sense slight movement of the airbag module 18.

In certain embodiments, the steering wheel assembly 20 comprises one or more buffers 72. In certain embodiments, the one or more buffers 72 are connected to the PCB 70. In certain embodiments, the airbag module 18 contacts an upper surface of the one or more buffers 72 when the airbag module 18 is installed within the central portion 54. In certain embodiments, the one or more buffers 72 are made of rubber or of another material. In the illustrated embodiment, there are four buffers 72. Of course the disclosure is not limited to the illustrated number of buffers 72 and can include more or fewer buffers 72 (e.g., one buffer 72, two buffers 72, three buffers 72, five buffers 72, six buffers 72, etc.).

In certain embodiments, the steering wheel assembly 20 comprises one or more fasteners 76. In certain embodiments, a shank of the one or more fasteners 76 passes through the PCB 70 and screws into the steering wheel assembly 20. In certain embodiments, the one or more fasteners 76 are made of metal or of another material. In the illustrated embodiment, there are four fasteners 76. Of course the disclosure is not limited to the illustrated number of fasteners 76 and can include more or fewer fasteners 76 (e.g., one fasteners 76, two fasteners 76, three fasteners 76, five fasteners 76, six fasteners 76, etc.).

FIG. 7 is a perspective view of the airbag module 18 showing one or more target surfaces 32 covered by Cu tape positioned to be in register with the one or more inductive sensors 30 when installed into the steering wheel assembly 20 of FIG. 6. In certain embodiments, the one or more target surfaces 32 are not covered by metallic tape. While the addition of the Cu tape can increase the sensitivity of the inductive sensor system 12, Cu tape is not required. Further, in certain embodiments, any metallic surface of the airbag module 18 can act as the target surface 32. For example, a surface of a screw or nut can be the target surface 32.

In certain embodiments, the steering wheel assembly 20 comprises one or more holes 74 (FIG. 6) for one or more locking pins 80 (FIG. 7). In certain embodiments, a distal portion of the one or more locking pins 80 pass through the one or more holes 74 in the PCB 70 and secure to the steering wheel assembly 20. In certain embodiments, the one or more locking pins 80 are made of metal or of another material. In the illustrated embodiment, there are two locking pins 80 and two corresponding holes 74. Of course the disclosure is not limited to the illustrated number of locking pins 80 or holes 74 and can include more or fewer locking pins 80 and holes 74.

FIG. 8 is a back side perspective view of a right switchpack 52A in an open position showing an inductance to digital converter 34 from FIG. 2 disposed in a receptacle 82. In certain embodiments, the inductance to digital converter 34 is connected to a printed circuit board (PCB) of the right switchpack 52A by a ribbon cable. In certain embodiments, the controller 14 (FIG. 2) is configured as the switchpack 52A. In certain embodiments, the inductance to digital converter 34 can be disposed in the second portion 58 and/or third portion 60 of the steering wheel assembly 20. In certain embodiments, the controller 14 is disposed in the third portion 60. In certain embodiments, the controller 14 may embody a printed circuit board (PCB).

FIG. 9 shows top and bottom views of two PCBs 70 similar to the PCB 70 from FIG. 6. As is illustrated in FIG. 9, in certain embodiments the PCB 70 is electrically connected to the inductance to digital converter 34. FIG. 10 illustrates another embodiment of the inductive sensor system 12 where the inductance to digital converter 34 is incorporated into the PCB of the right switchpack 52A.

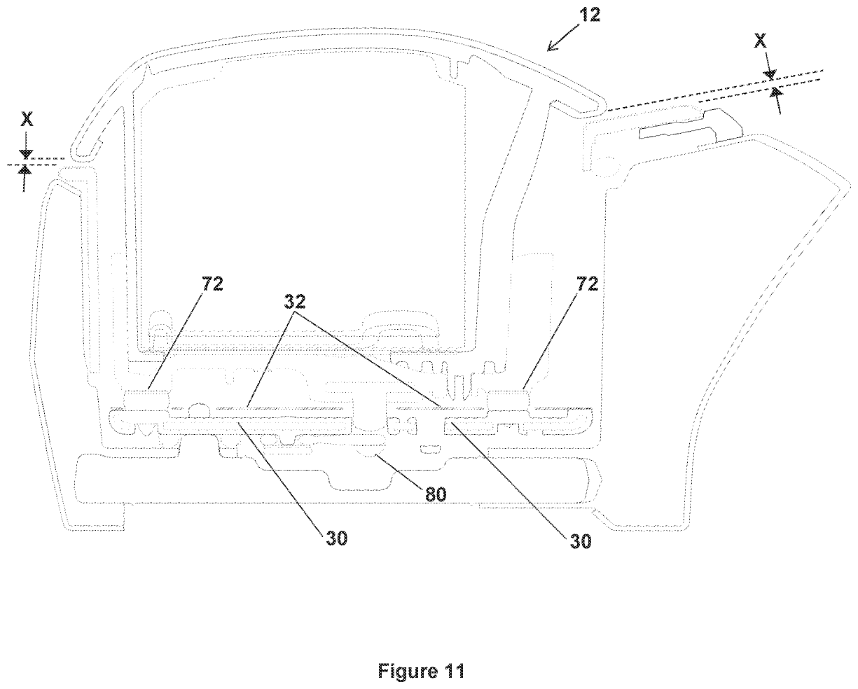

Figure ii is a cross-section view through the steering wheel assembly 20 of FIG. 4 showing the inductive sensors 30 in proximity to the target surfaces 32. FIG. 11 further shows a small gap X around an outer perimeter of the airbag module 18. Since the inductive sensor system 12 does not require the travel distance of mechanical switches, there is no need to maintain a significant gap around the outer perimeter of the airbag module 18. In this way, the appearance of the steering wheel assembly 20 is improved. Further, without the need for mechanical travel, any undesirable squeaks and noises from springs and contacts are also avoided.

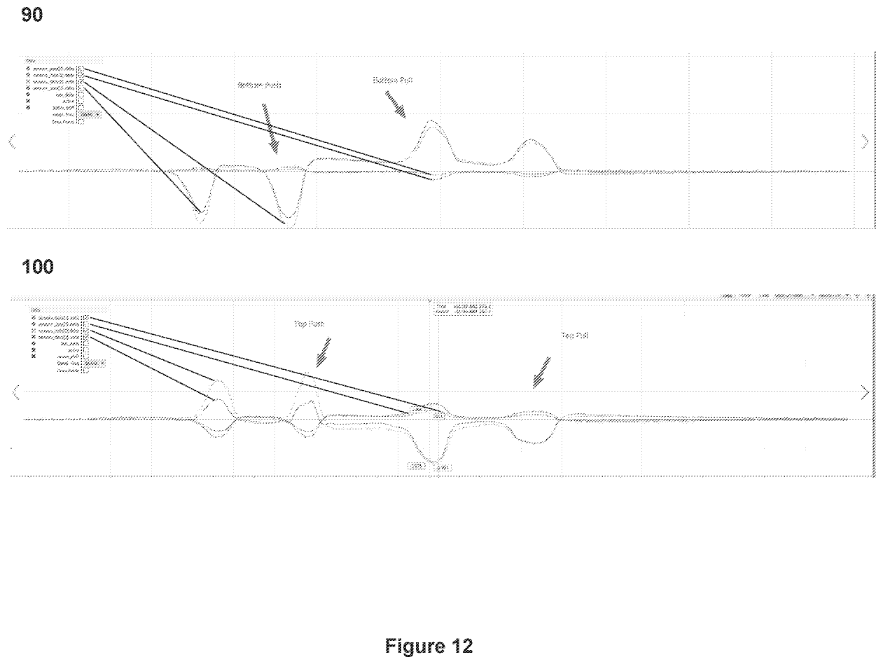

FIG. 12 are exemplary charts of sensor data 90, 100 measured by the inductive sensor system 12 of FIG. 2 in response to the user pushing or pulling near the top and bottom of the airbag module 18. Unlike conventional horn designs, as is illustrated in FIG. 12, the horn can be activated by pushing or pulling on the airbag module 18. In certain embodiments, the gain and sensitivity of the inductive sensor system 12 is adjustable by software. For example, in certain embodiments, the force required to activate or trigger the horn can be updatable post-delivery of the vehicle 40. For example, in certain embodiments, the force required to activate or trigger the horn can be adjusted to allow for dynamic sensitivity based on driving conditions/harshness, or even user preference. In this way, dynamic springs and mechanical contacts of existing horn actuation mechanisms are replaced with static coils 30 and target surfaces 32, potentially reducing cost and environmental mitigations.

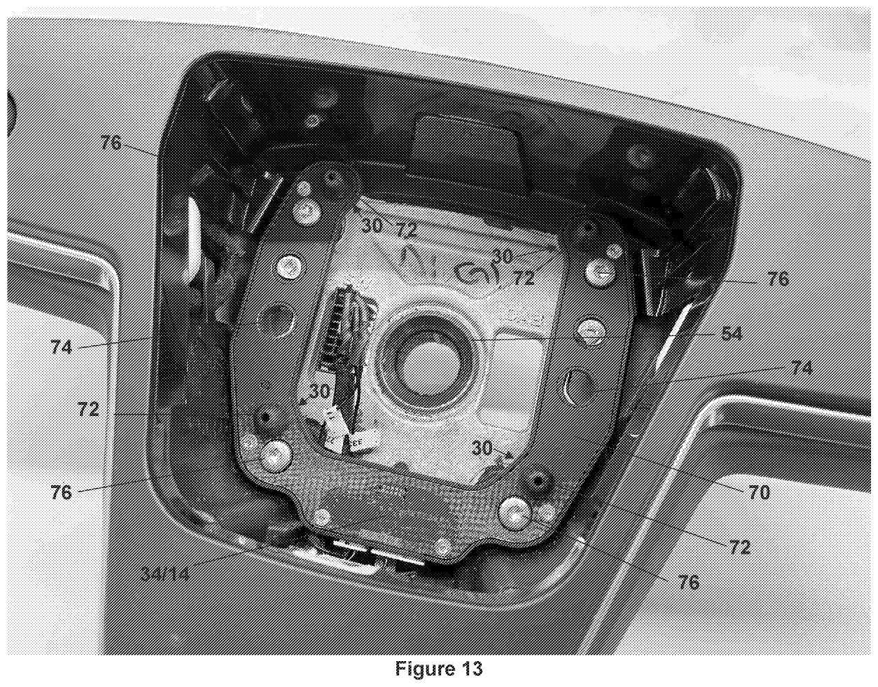

FIG. 13 is a plan view of an embodiment of the steering wheel assembly 20 from FIG. 5 with the airbag module 18 removed. In the embodiment illustrated in FIG. 13, the controller 14 and/or the inductance to digital converter 34 is integrated into the printer circuit board (PCB) 70. For example, in certain embodiments, the controller 14 is integrated into the printer circuit board (PCB) 70. For example, in certain embodiments, the inductance to digital converter 34 is integrated into the printer circuit board (PCB) 70. In certain embodiments, the controller 14 and the inductance to digital converter 34 are integrated into the printer circuit board (PCB) 70. In certain embodiments, the PCB 70 is a flexible PCB, a rigid PCB, or a rigid-flex PCB. In the embodiment illustrated in FIG. 13, the PCB 70 is a rigid PCB.

In certain embodiments, the steering wheel assembly 20 comprises the one or more buffers 72. In certain embodiments, the one or more buffers 72 are connected to the PCB 70. In certain embodiments, the airbag module 18 contacts an upper surface of the one or more buffers 72 when the airbag module 18 is installed within the central portion 54. In certain embodiments, the one or more buffers 72 are made of rubber or of another material. In the illustrated embodiment, there are four buffers 72. Of course the disclosure is not limited to the illustrated number of buffers 72 and can include more or fewer buffers 72 (e.g., one buffer 72, two buffers 72, three buffers 72, five buffers 72, six buffers 72, etc.).

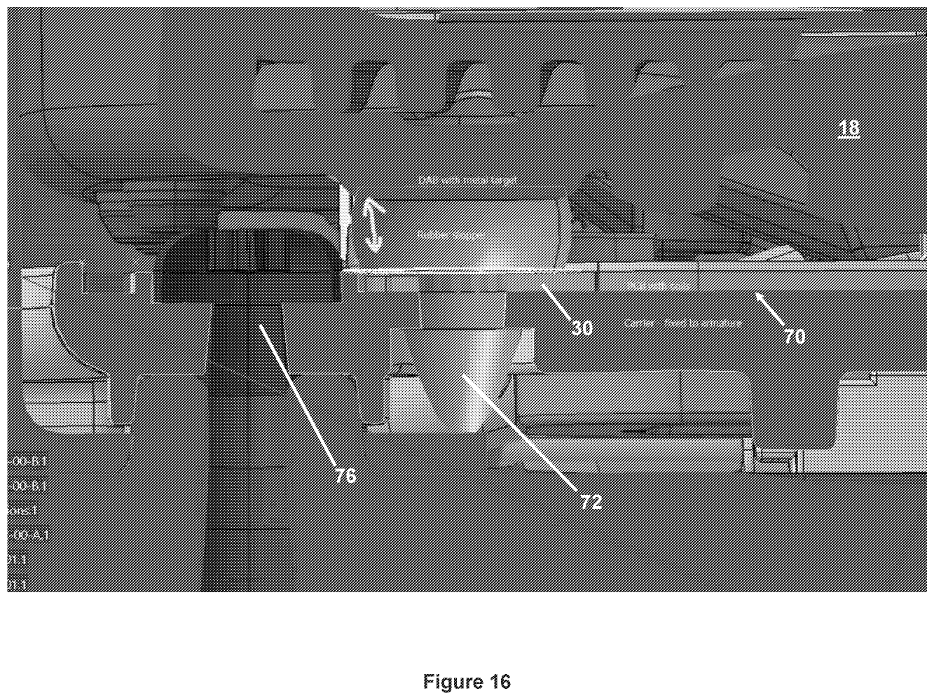

In the illustrated embodiment, there are four inductive sensors 30 integrated into the PCB 70 and positioned underneath and around the one or more buffers 72. An exemplary inductive sensor 30 is shown in FIG. 16 integrated within the PCB 70. Of course the disclosure is not limited to the illustrated number of inductive sensors 30 and can include more or fewer inductive sensors 30 (e.g., one sensor 30, two sensors 30, three sensors 30, five sensors 30, six sensors 30, etc.). The locations of the one or more inductive sensors 30 in FIG. 13 being underneath the one or buffers 72 are only exemplary and can instead be in any other position within the central portion 54 that is in proximity to the airbag module 18 so as to sense slight movement of the airbag module 18.

In certain embodiments, the controller 14 is electrically connected to the at least one inductive sensor 30 (e.g., via the inductance to digital converter 34). The controller 14 can determine a user input or a gesture made by a user on the target surface 32 based on the change measured by the inductance to digital converter 34.

In certain embodiments, the controller 14 is located in the inductive sensor system 12. In certain embodiments, the controller 14 and/or the inductance to digital converter 34 is located in the steering wheel assembly 20. In certain embodiments, the controller 14 is located in the vehicle 40. In certain embodiments that include multiple controllers 14, each controller 14 can be associated with one or more inductive sensors 30.

In certain embodiments, the controller 14 is configured to control the inductive sensor system 12 during a calibration process. In certain embodiments, the controller 14 is configured to control the inductive sensor system 12, e.g., command operational parameters, during not only the calibration process but also during operation of the vehicle 40 by the user. In certain embodiments, the calibration process is performed in preparation for delivery of the vehicle 40 to the user. In certain embodiments, the calibration process for the inductive sensor system 12 is repeated one or more times after delivery of the vehicle 40 to the user.

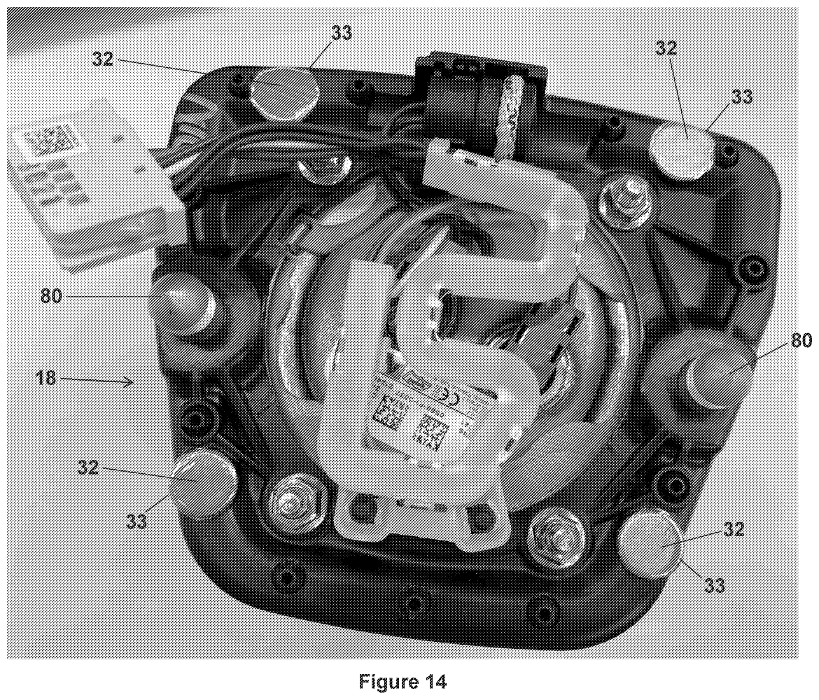

FIG. 14 is a perspective view of an embodiment of the airbag module 18 showing one or more target surfaces 32 covered by Cu tape 33 positioned to be in register with the one or more inductive sensors 30 when installed into the steering wheel assembly 20 of FIG. 13 according to an embodiment of the present disclosure. In certain embodiments, the one or more target surfaces 32 are not covered by metallic tape. While the addition of the Cu tape 33 can increase the sensitivity of the inductive sensor system 12, Cu tape 33 is not required. Further, in certain embodiments, any metallic surface of the airbag module 18 can act as the target surface 32. For example, a surface of a screw or nut can be the target surface 32.

FIG. 15 shows a perspective view of a PCB 70 that integrates the inductance to digital converter 34 and/or the controller 14 from FIG. 2. FIG. 16 is a partial cross section view taken along lines 16-16 of FIG. 15 showing the one or more inductive sensors 30 integrated into the PCB 70 and positioned underneath and around the one or more buffers 72. Locating the inductive sensors 30 underneath the buffers 72 may provide the additional advantage of reducing any impact on the sensed signal caused by rocking of the airbag module 18 which may occur if the inductive sensors 30 are instead laterally offset from the buffers 72. In this way, the inductive sensors 30 directly sense the compression which occurs under the “spring” (e.g., buffers 72) due to movement of the airbag module 18. Locating the inductive sensors 30 underneath the buffers 72 may provide packaging advantages as well. The illustrated PCB 70 comprises four buffers 72 and four inductive sensors 30 positioned underneath and around the four buffers 72. Of course, the disclosure is not limited to the illustrated number of buffers 72 and can include more or fewer buffers 72 (e.g., one buffer 72, two buffers 72, three buffers 72, five buffers 72, six buffers 72, etc.).

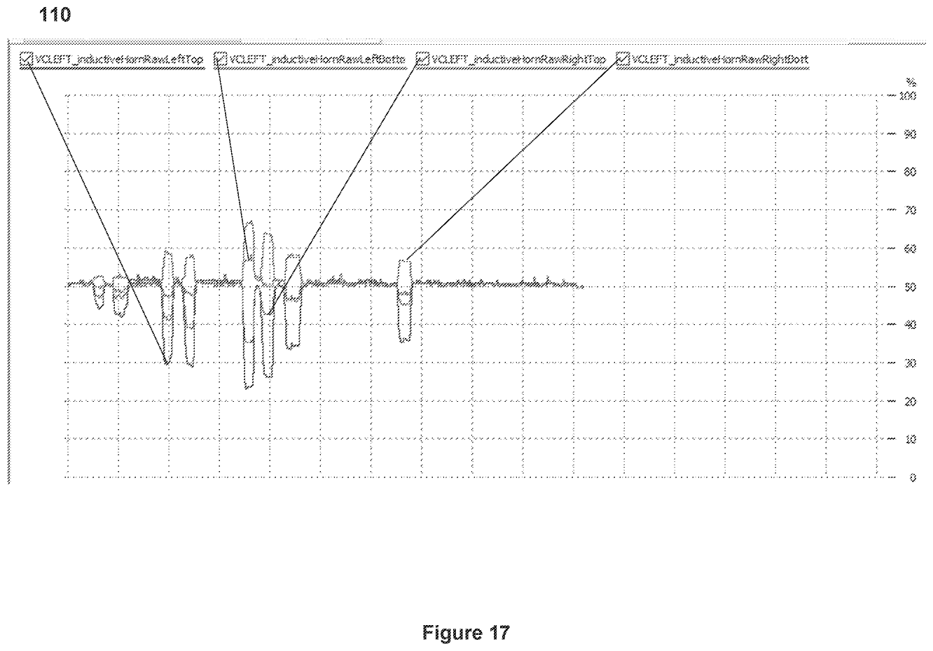

FIG. 17 is an exemplary chart of sensor data 110 measured by an embodiment of the inductive sensor system that includes the PCB 70 of FIG. 15 in response to the user pushing or pulling on the airbag module 18. Unlike conventional horn designs, as is illustrated in FIG. 17, the horn can be activated by pushing or pulling on the airbag module 18. In certain embodiments, the gain and sensitivity of the inductive sensor system 12 is adjustable by software. For example, in certain embodiments, the force required to activate or trigger the horn can be updatable post-delivery of the vehicle 40. For example, in certain embodiments, the force required to activate or trigger the horn can be adjusted to allow for dynamic sensitivity based on driving conditions/harshness, or even user preference. In this way, dynamic springs and mechanical contacts of existing horn actuation mechanisms are replaced with static coils 30 and target surfaces 32, potentially reducing cost and environmental mitigations.

In certain embodiments, the inductive sensor system 12 senses different applied forces (e.g., pressure and/or location on the airbag module 18) and in response triggers a specific horn sound and/or broadcast direction associated with the applied force. For example, in certain embodiments, the horn sound volume can be proportional to applied forces and/or emitted in a specific direction away from the vehicle 40. In certain embodiments, the user can reduce the volume of the horn by applying less force to the airbag module 18.

Advantageously, the calibration process can be performed at any point during the manufacturing process, and can be re-commanded at any point during the life of the steering wheel assembly 20 without employing external measurement equipment. For example, the calibration process can be applied during the manufacturing process automatically, so there is no need for manual calibration. For example, the calibration process can be applied during an initial fitting to the customer or at a distribution center. The calibration process can also be applied remotely or in service if a user experiences a degradation in quality (e.g., sensitivity). This degradation can occur if, for example, any of the mechanical contributions in the force/displacement stack of components change over time (e.g., one or more buffers 72 degrade over time and become stiffer or softer).

In certain embodiments, software data associated with the calibration process may be updated from time to time. In certain embodiments, an over-the-air (OTA) update is used to add, subtract, alter, or initiate the calibration process. For example, after the vehicle 40 is delivered to the user, an OTA update may initiate the calibration process. Depending on the results of the calibration process, the controller 14 may alter one or more characteristics (e.g., gain) of inductive sensor system 12. OTA updates open possibilities to adjust the horn sensitivity, including based on real-time user data after the vehicle 40 is delivered or based on driver feedback.

In certain embodiments, the system 10 can output an indication of a level of its calibration. For example, in certain embodiments, the inductive sensor system 12 can be calibrated to a specific level of sensitivity (e.g., low sensitivity or high sensitivity) with an indication of the level of sensitivity being available to be output by the system 10. If a user identifies a problem/issue with the level of sensitivity they experience, the system 10 can implement a confirmation process to determine the current level is the desired level of the user.

The foregoing disclosure is not intended to limit the present disclosure to the precise forms or particular fields of use disclosed. As such, it is contemplated that various alternate embodiments and/or modifications to the present disclosure, whether explicitly described or implied herein, are possible in light of the disclosure. Having thus described embodiments of the present disclosure, a person of ordinary skill in the art will recognize that changes may be made in form and detail without departing from the scope of the present disclosure. Thus, the present disclosure is limited only by the claims.

In the foregoing specification, the disclosure has been described with reference to specific embodiments. However, as one skilled in the art will appreciate, various embodiments disclosed herein can be modified or otherwise implemented in various other ways without departing from the spirit and scope of the disclosure. Accordingly, this description is to be considered as illustrative and is for the purpose of teaching those skilled in the art the manner of making and using various embodiments of the disclosed horn actuation assembly. It is to be understood that the forms of disclosure herein shown and described are to be taken as representative embodiments. Equivalent elements, materials, processes or steps may be substituted for those representatively illustrated and described herein. Moreover, certain features of the disclosure may be utilized independently of the use of other features, all as would be apparent to one skilled in the art after having the benefit of this description of the disclosure. Expressions such as “including”, “comprising”, “incorporating”, “consisting of”, “have”, “is” used to describe and claim the present disclosure are intended to be construed in a non-exclusive manner, namely allowing for items, components or elements not explicitly described also to be present. Reference to the singular is also to be construed to relate to the plural.

Further, various embodiments disclosed herein are to be taken in the illustrative and explanatory sense, and should in no way be construed as limiting of the present disclosure. All joinder references (e.g., attached, affixed, coupled, connected, and the like) are only used to aid the reader's understanding of the present disclosure, and may not create limitations, particularly as to the position, orientation, or use of the systems and/or methods disclosed herein. Therefore, joinder references, if any, are to be construed broadly. Moreover, such joinder references do not necessarily infer that two elements are directly connected to each other. Additionally, all numerical terms, such as, but not limited to, “first”, “second”, “third”, “primary”, “secondary”, “main” or any other ordinary and/or numerical terms, should also be taken only as identifiers, to assist the reader's understanding of the various elements, embodiments, variations and/or modifications of the present disclosure, and may not create any limitations, particularly as to the order, or preference, of any element, embodiment, variation and/or modification relative to, or over, another element, embodiment, variation and/or modification.

It will also be appreciated that one or more of the elements depicted in the drawings/figures can also be implemented in a more separated or integrated manner, or even removed or rendered as inoperable in certain cases, as is useful in accordance with a particular application.

1. A system for triggering a functionality of a vehicle, comprising:
an inductive sensor;
a vehicle interface;
a conductive target coupled to the vehicle interface and configured to move with the vehicle interface between a first position and a second position relative to the inductive sensor, the first position having a first inductance and the second position having a second inductance different than the first inductance; and
a controller configured to:
receive a signal from the inductive sensor indicative of a change between the first inductance and the second inductance, and
trigger the functionality of the vehicle.

2. The system of claim 1, wherein the functionality includes activating a horn.

3. The system of claim 1, wherein the vehicle interface comprises a steering wheel assembly that includes an airbag module.

4. The system of claim 3, wherein the conductive target is disposed upon a surface of the airbag module and the inductive sensor is disposed upon the steering wheel assembly.

5. (canceled)

6. (canceled)

7. The system of claim 1, wherein the conductive target includes Cu tape.

8. (canceled)

9. (canceled)

10. The system of claim 1, wherein the signal indicates a measure of force applied to the vehicle interface, wherein the triggering the functionality comprises emitting a sound, and wherein a volume level of the sound is based on the measure of the force.

11. (canceled)

12. The system of claim 1, wherein the signal is indicative of at least a location of force applied to the vehicle interface, and wherein the functionality is based on the location of the force.

13. The system of claim 12, wherein the functionality includes emitting a sound that comprises a broadcast direction based on the location of the force.

14. The system of claim 1, further comprising a memory configured to store values or settings related to the functionality.

15. (canceled)

16. The system of claim 1, further comprising a buffer disposed between the inductive sensor and the conductive target

17. The system of claim 16, wherein the buffer comprises a rubber buffer.

18. (canceled)

19. (canceled)

20. The system of claim 1, further comprising a steering wheel assembly having a center portion, and wherein the vehicle interface is sized and shaped so that at least a portion of the vehicle interface fits within the center portion.

21. (canceled)

22. A steering wheel assembly for a vehicle, comprising;
at least one target surface disposed on an airbag module; and
at least one inductive sensor adapted to generate a signal in response to changes in a measured inductance caused by a change in distance between the at least one inductive sensor and the at least one target surface.

23. (canceled)

24. The system of claim 22, further comprising a buffer disposed between the at least one inductive sensor and the at least one target surface.

25. (canceled)

26. A method for triggering a functionality of a vehicle, the vehicle comprising at least one target surface and at least one inductive sensor disposed relative to the at least one target surface to sense movement of the target surface, comprising:
moving the at least one target surface to change a distance between the at least one target surface and the at least one inductive sensor;
generating a signal in response to a change in a measured inductance caused by the change in the distance; and
triggering the functionality of the vehicle based on the signal.

27. The method of claim 26, wherein the functionality includes activating a horn.

28. The method of claim 26, wherein the at least one target surface is disposed on an airbag module, and the inductive sensor is disposed upon a steering wheel assembly.

29.-34. (canceled)

35. The method of claim 28, wherein the signal indicates a measure of force, and wherein the triggering the functionality of the vehicle is based on the measure of the force.

36. The method of claim 35, wherein the functionality of the vehicle includes emitting a sound, and wherein a volume of the sound is based on the measure of the force.
